(19) United States
(12) Patent Application Publication
(10) Pub. No.: US 2024/0387112 A1
(43) Pub. Date: Nov. 21, 2024

(54) MULTILAYER CERAMIC CAPACITOR, MULTILAYER-CERAMIC-CAPACITOR MANUFACTURING METHOD, AND MULTILAYER-CERAMIC-CAPACITOR MOUNTING STRUCTURE

(71) Applicant: Murata Manufacturing Co., Ltd., Nagaokakyo-shi (JP)

(72) Inventor: Toshiyuki NAKAMURA, Nagaokakyo-shi (JP)

(21) Appl. No.: 18/788,314

(22) Filed: Jul. 30, 2024

Related U.S. Application Data
(63) Continuation of application No. PCT/JP2023/009471, filed on Mar. 12, 2023.

(30) Foreign Application Priority Data
Apr. 1, 2022 (JP) 2022-062105

(51) Int. Cl. H01G 4/232; H01G 4/30; H05K 1/18

(52) U.S. Cl. CPC H01G 4/2325; H01G 4/30; H05K 1/181; H05K 2201/10015

(57) ABSTRACT

A multilayer ceramic capacitor includes a first end-surface electrode covering portions of first and second main surfaces and first and second side surfaces, a second end-surface electrode covering portions of the first and second main surfaces and first and second side surfaces, a first side-surface electrode covering portions of the first and second main surfaces, and a second side-surface electrode covering portions of the first main surface and the second main surface, the first and second internal electrodes being connected to the first and second end-surface electrodes. The first and second end-surface electrodes each include a first base electrode layer and first and second plating electrode layers, and the first and second side-surface electrodes each include a second base electrode layer and third, fourth, fifth, and sixth plating electrode layers.

### CROSS REFERENCE TO RELATED APPLICATIONS

This application claims the benefit of priority to Japanese Patent Application No. 2022-062105 filed on Apr. 1, 2022 and is a Continuation Application of PCT Application No. PCT/JP2023/009471 filed on Mar. 12, 2023. The entire contents of each application are hereby incorporated herein by reference.

### BACKGROUND OF THE INVENTION

### 1. Field of the Invention

The present invention relates to multilayer ceramic capacitors and, more particularly, relates to multilayer ceramic capacitors each including a first end-surface electrode, a second end-surface electrode, a first side-surface electrode, and a second side-surface electrode. The present invention also relates to multilayer-ceramic-capacitor manufacturing methods suitable for manufacturing the multilayer ceramic capacitors of the present invention. Furthermore, the present invention relates to multilayer-ceramic-capacitor mounting structures capable of being implemented using the multilayer ceramic capacitors of the present invention.

### 2. Description of the Related Art

Multilayer ceramic capacitors called three-terminal multilayer ceramic capacitors have been widely used in consideration of, for example, noise reduction. For example, Japanese Unexamined Patent Application, Publication No. 2020-167236 discloses a three-terminal multilayer ceramic capacitor.

The multilayer ceramic capacitor disclosed in Japanese Unexamined Patent Application, Publication No. 2020-167236 includes a multilayer body (capacitive element) in which a plurality of ceramic layers, a plurality of first internal electrodes, and a plurality of second internal electrodes are stacked. The multilayer body has a first main surface, a second main surface, a first end surface, a second end surface, a first side surface, and a second side surface. The first main surface is a mounting surface of the multilayer ceramic capacitor that is to be mounted on, for example, a board.

The multilayer ceramic capacitor disclosed in Japanese Unexamined Patent Application, Publication No. 2020-167236 includes a first end-surface electrode that is provided on the first end surface of the multilayer body and extends from the first end surface so as to cover portions of the first main surface, the second main surface, the first side surface, and the second side surface; a second end-surface electrode that is provided on the second end surface and extends from the second end surface so as to cover portions of the first main surface, the second main surface, the first side surface, and the second side surface, a first side-surface electrode that is provided on the first side surface and extends from the first side surface so as to cover portions of the first main surface and the second main surface, and a second side-surface electrode that is provided on the second side surface and extends from the second side surface so as to cover portions of the first main surface and the second main surface. The first internal electrodes are connected to the first and second end-surface electrodes, and the second internal electrodes are connected to the first and second side-surface electrodes.

In the multilayer ceramic capacitor disclosed in Japanese Unexamined Patent Application, Publication No. 2020-167236, the first and second end-surface electrodes and the first and second side-surface electrodes are formed so as to have the same multilayer structure, and the layers are the same in material and thickness dimension. Thus, the first and second end-surface electrodes and the first and second side-surface electrodes have the same thickness dimension. Accordingly, if the multilayer ceramic capacitor disclosed in Japanese Unexamined Patent Application, Publication No. 2020-167236 is mounted on a board provided with first to fourth land electrodes so as to respectively bond the first land electrode, the second land electrode, the third land electrode, and the fourth land electrode to the first end-surface electrode, the second end-surface electrode, the first side-surface electrode, and the second side-surface electrode by reflow soldering, the solder between the first land electrode and the first end-surface electrode, the solder between the second land electrode and the second end-surface electrode, the solder between the third land electrode and the first side-surface electrode, and the solder between the fourth land electrode and the second side-surface electrode will be the same in thickness dimension.

With respect to the multilayer ceramic capacitor disclosed in Japanese Unexamined Patent Application, Publication No. 2020-167236, the first and second end-surface electrodes can be connected to intermediate portions of a power supply line or a signal line, and the first and second side-surface electrodes can be connected to a ground potential, thereby removing unnecessary noise flowing through the line.

### SUMMARY OF THE INVENTION

When the multilayer ceramic capacitor disclosed in Japanese Unexamined Patent Application, Publication No. 2020-167236 is mounted on a board, if stress is applied to the board and thus the board is flexed (or torsionally deformed), the stress is transferred to the multilayer ceramic capacitor via solder, and the portions of the ceramic multilayer body where the first and second end-surface electrodes are formed and the vicinities of these portions may be cracked or chipped. The stress is relatively unlikely to be transferred to the portions of the multilayer body where the first and second side-surface electrodes are formed and the vicinities of these portions, and thus such portions are less likely to be cracked or chipped than the portions where the first and second end-surface electrodes are formed and the vicinities of these portions.

Accordingly, an example embodiment of the present invention provides a multilayer ceramic capacitor configured such that cracks or chips in a multilayer body are reduced or prevented even when stress is applied to a board mounted with the multilayer ceramic capacitor and thus the board is flexed.

A multilayer ceramic capacitor according to an example embodiment of the present invention includes a multilayer body including a plurality of ceramic layers, a plurality of first internal electrodes, and a plurality of second internal electrodes stacked in a height direction, a first main surface and a second main surface opposed to each other in the height direction, a first end surface and a second end surface opposed to each other in a lengthwise direction orthogonal to the height direction, and a first side surface and a second side surface opposed to each other in a width direction orthogonal to the height direction and the lengthwise direction, a first end-surface electrode on the first end surface and extending from the first end surface so as to cover portions of the first main surface, the second main surface, the first side surface, and the second side surface, a second end-surface electrode on the second end surface and extending from the second end surface so as to cover portions of the first main surface, the second main surface, the first side surface, and the second side surface, a first side-surface electrode on the first side surface and extending from the first side surface so as to cover portions of the first main surface and the second main surface; and a second side-surface electrode on the second side surface and extending from the second side surface so as to cover portions of the first main surface and the second main surface, the first internal electrodes being connected to the first end-surface electrode and the second end-surface electrode, the second internal electrodes being connected to the first side-surface electrode and the second side-surface electrode, in which the first end-surface electrode and the second end-surface electrode each include a first base electrode layer, a first plating electrode layer on the first base electrode layer, and a second plating electrode layer on the first plating electrode layer, and the first side-surface electrode and the second side-surface electrode each include a second base electrode layer, a third plating electrode layer on the second base electrode layer, a fourth plating electrode layer on the third plating electrode layer, a fifth plating electrode layer on the fourth plating electrode layer, and a sixth plating electrode layer on the fifth plating electrode layer.

A multilayer-ceramic-capacitor mounting structure according to another example embodiment of the present invention a board, and a multilayer ceramic capacitor mounted on the board, the multilayer ceramic capacitor including a multilayer body including a plurality of ceramic layers, a plurality of first internal electrodes, and a plurality of second internal electrodes stacked in a height direction, a first main surface and a second main surface opposed to each other in the height direction, a first end surface and a second end surface opposed to each other in a lengthwise direction orthogonal to the height direction, and a first side surface and a second side surface opposed to each other in a width direction orthogonal to the height direction and the lengthwise direction, a first end-surface electrode that is on the first end surface and extends from the first end surface so as to cover portions of the first main surface, the second main surface, the first side surface, and the second side surface, a second end-surface electrode that is on the second end surface and extends from the second end surface so as to cover portions of the first main surface, the second main surface, the first side surface, and the second side surface, a first side-surface electrode that is on the first side surface and extends from the first side surface so as to cover portions of the first main surface and the second main surface, and a second side-surface electrode that is on the second side surface and extends from the second side surface so as to cover portions of the first main surface and the second main surface, the first internal electrodes are connected to the first end-surface electrode and the second end-surface electrode, the second internal electrodes are connected to the first side-surface electrode and the second side-surface electrode, the first end-surface electrode and the second end-surface electrode each include a first base electrode layer and a first plating electrode layer on the first base electrode layer, and the first side-surface electrode and the second side-surface electrode each include a second base electrode layer, a third plating electrode layer on the second base electrode layer, a fourth plating electrode layer on the third plating electrode layer, and a fifth plating electrode layer on the fourth plating electrode layer, the board includes a main surface on which a first land electrode, a second land electrode, a third land electrode, and a fourth land electrode are provided, the first end-surface electrode, the second end-surface electrode, the first side-surface electrode, and the second side-surface electrode are respectively bonded to the first land electrode, the second land electrode, the third land electrode, and the fourth land electrode with a bonding material, and a thickness dimension of the bonding material present between the first end-surface electrode and the first land electrode and a thickness dimension of the bonding material present between the second end-surface electrode and the second land electrode are each greater than a thickness dimension of the bonding material present between the first side-surface electrode and the third land electrode and a thickness dimension of the bonding material present between the second side-surface electrode and the fourth land electrode.

A multilayer ceramic capacitor according to an example embodiment of the present invention reduces or prevents cracks or chips in a multilayer body even when stress is applied to a board mounted with the multilayer ceramic capacitor and thus the board is flexed.

A multilayer-ceramic-capacitor mounting structure according to an example embodiment of the present invention reduces or prevents cracks or chips in the multilayer body of the multilayer ceramic capacitor even when stress is applied to the board and thus the board is flexed.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a multilayer ceramic capacitor 100.

FIG. 2 is a cross-sectional view of the multilayer ceramic capacitor 100 that illustrates an X-X portion indicated by a dashed-dotted-line arrow in FIG. 1.

FIG. 3 is a main portion exploded perspective view of the multilayer ceramic capacitor 100.

FIG. 4 is an explanatory view (cross-sectional view) of a mounting structure 200.

FIGS. 5A to 5C are each an explanatory view illustrating a step that is performed in a first manufacturing method for the multilayer ceramic capacitor 100.

FIGS. 6D to 6F are each an explanatory view illustrating a step that is performed after the step of FIG. 5C in the first manufacturing method for the multilayer ceramic capacitor 100.

FIGS. 7A to 7C are each an explanatory view illustrating a step that is performed in a second manufacturing method for the multilayer ceramic capacitor 100.

FIGS. 8D and 8E are each an explanatory view illustrating a step that is performed after the step of FIG. 7C in the second manufacturing method for the multilayer ceramic capacitor 100.

FIGS. 9F and 9G are each an explanatory view illustrating a step that is performed after the step of FIG. 8E in the second manufacturing method for the multilayer ceramic capacitor 100.

### DETAILED DESCRIPTION OF THE EXAMPLE EMBODIMENTS

The following describes example embodiments of the present invention in conjunction with the drawings. Example embodiments indicate possible implementation modes of the present invention, and the present invention is not limited to the features of the example embodiments. A combination of features described with reference to different example embodiments can be implemented, and the present invention also encompasses the implemented features in such a situation. The drawings are provided to aid in the understanding of the description and may present schematically illustrated features, and illustrated components or the ratio in dimension between components may be inconsistent with the ratio in dimension therebetween disclosed in the description. Components disclosed in the description may be omitted in the drawings, or the number of such components may be decreased for simplicity in the drawings.

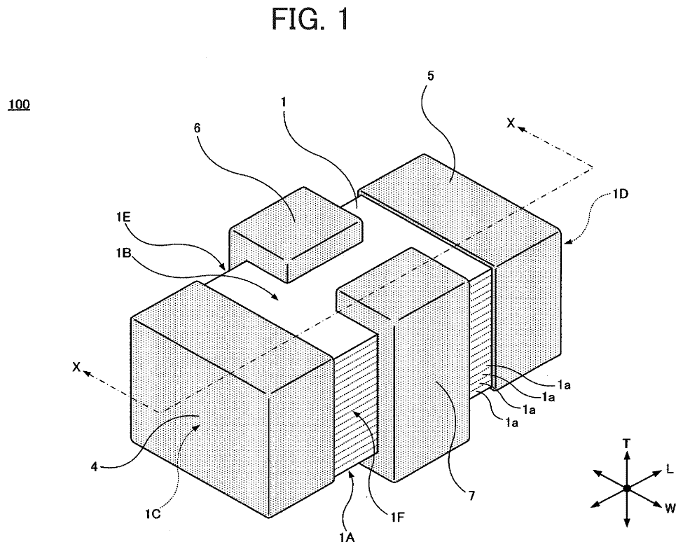

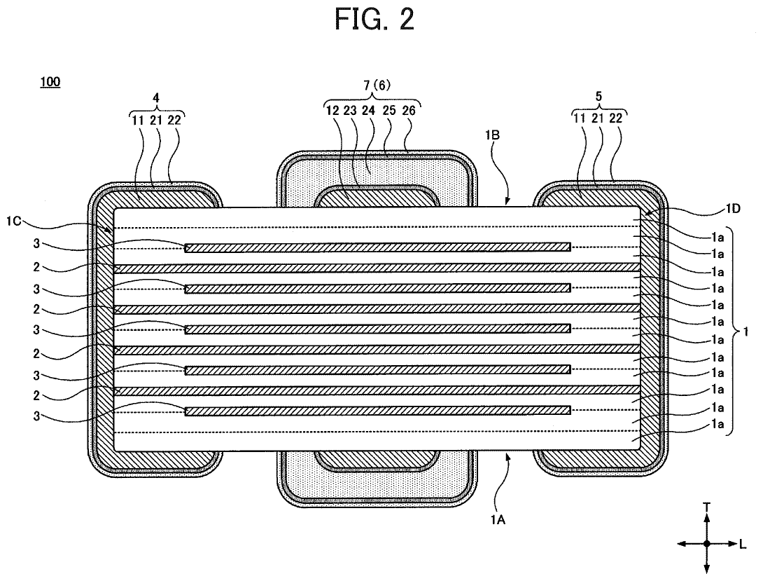

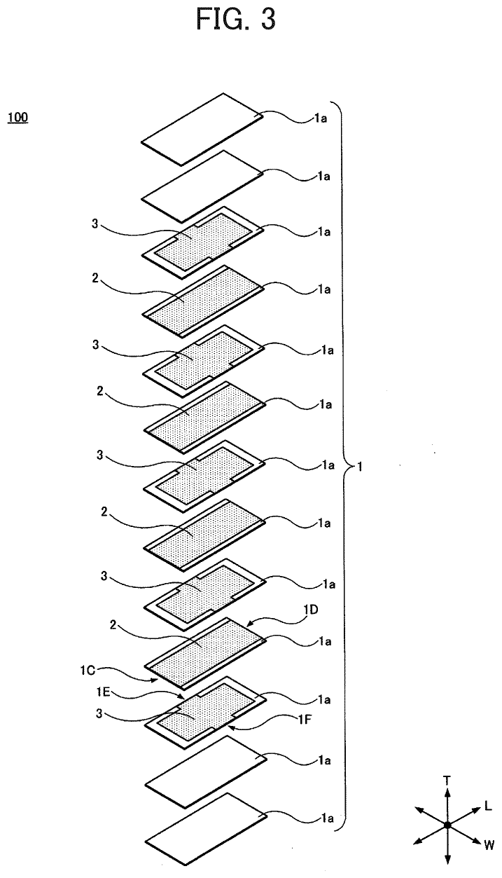

FIGS. 1 to 3 each illustrate a multilayer ceramic capacitor 100 according to an example embodiment of the present invention. FIG. 1 is a perspective view of the multilayer ceramic capacitor 100. FIG. 2 is a cross-sectional view of the multilayer ceramic capacitor 100 that illustrates an X-X portion indicated by a dashed-dotted-line arrow in FIG. 1. FIG. 3 is a main portion exploded perspective view of the multilayer ceramic capacitor 100. These figures indicate a height direction T, a lengthwise direction L, and a width direction W of the multilayer ceramic capacitor 100, and reference may be made to these directions in the following. In the present example embodiment, the lamination direction of ceramic layers 1a described hereinafter is defined as the height direction T of the multilayer ceramic capacitor 100.

The multilayer ceramic capacitor 100 includes a multilayer body 1 having a cuboid shape. The multilayer body 1 includes a first main surface 1A and a second main surface 1B opposed to each other in the height direction T, a first end surface 1C and a second end surface 1D opposed to each other in the lengthwise direction L orthogonal to the height direction T, and a first side surface 1E and a second side surface 1F opposed to each other in the width direction W orthogonal to both the height direction T and the lengthwise direction L.

The multilayer body 1 may have any dimensions, and, for example, the dimension in the lengthwise direction L may be approximately 100 μm to 5700 μm, the dimension in the width direction W may be approximately 100 μm to 5000 μm, and the dimension in the height direction T may be approximately 100 μm to 2500 μm.

The multilayer body 1 includes a plurality of ceramic layers 1a, a plurality of first internal electrodes 2, and a plurality of second internal electrodes 3 that are stacked atop one another.

The multilayer body 1 (ceramic layers 1a) may include any material. For example, dielectric ceramics including BaTiO₃ as a main component may be used for the multilayer body 1. However, dielectric ceramics including another material such as CaTiO₃, SrTiO₃, or CaZrO₃ as a main component, rather than BaTiO₃, may also be used.

The ceramic layers 1a may each have any thickness, which may be, for example, approximately 0.3 μm to 2.0 μm in an effective region for capacitance generation in which the first internal electrodes 2 and the second internal electrodes 3 are provided.

There may be any number of ceramic layers 1a. For example, there may be 1 to 6000 ceramic layers 1a in the effective region for capacitance generation in which the first internal electrodes 2 and the second internal electrodes 3 are formed.

None of the first internal electrodes 2 and the second internal electrodes 3 are formed on the upper or lower side of the multilayer body 1, but outer layers (protective layers) formed from ceramic layers 1a alone are provided thereon. The outer layers may have any thickness, which may be, for example, about 15 μm to about 150 μm. The thickness of the ceramic layers 1a in the outer layer regions may be greater than the thickness of the ceramic layers 1a in the effective region for capacitance generation in which the first internal electrodes 2 and the second internal electrodes 3 are formed (in FIGS. 1 to 3, however, the thickness of the ceramic layers 1a in the outer layer regions is indicated as being the same as that in the effective region). The ceramic layers 1a in the outer layer regions may be different in material from the ceramic layers 1a in the effective region.

In the main portion exploded perspective view of FIG. 3, the multilayer body 1 has been separated into ceramic layers 1a. As seen in FIG. 3, the first internal electrodes 2 extend in the lengthwise direction L of the multilayer ceramic capacitor 100 and are led to the first end surface 1C and the second end surface 1D of the multilayer body 1. The second internal electrodes 3 extend in the lengthwise direction L of the multilayer ceramic capacitor 100 and are led to the first side surface 1E and the second side surface 1F of the multilayer body 1. In principle, the first internal electrode layers 2 and the second internal electrode layers 3 are stacked in an alternating pattern.

The first internal electrodes 2 and the second internal electrodes 3 may include any material as a main component, and Ni is used as the main component in present example embodiment. However, another metal such as Cu, Ag, Pd, or Au may be used instead of Ni. Alternatively, an alloy of Ni and another metal or an alloy of Cu, Ag, Pd, Au, or the like and another metal may be used.

The first internal electrodes 2 and the second internal electrodes 3 may have any thickness, which may be, for example, approximately 0.3 μm to 1.5 μm.

A first end-surface electrode 4, a second end-surface electrode 5, a first side-surface electrode 6, and a second side-surface electrode 7 are provided on the outer surfaces of the multilayer body 1 as external electrodes.

The first end-surface electrode 4 is provided on the first end surface 1C and extends from the first end-surface electrode 1C so as to cover portions of the first main surface 1A, the second main surface 1B, the first side surface 1E, and the second side surface 1F.

The second end-surface electrode 5 is provided on the second end surface 1D and extends from the second end surface 1D so as to cover portions of the first main surface 1A, the second main surface 1B, the first side surface 1E, and the second side surface 1F.

The first side-surface electrode 6 is provided on the first side surface 1E and extends from the first side surface 1E so as to cover portions of the first main surface 1A and the second main surface 1B.

The second side-surface electrode 7 is provided on the second side surface 1F and extends from the second side surface 1F so as to cover portions of the first main surface 1A and the second main surface 1B.

The first internal electrodes 2, which are led to the first end surface 1C of the multilayer body 1, are connected to the first end-surface electrode 4. The first internal electrodes 2, which are led to the second end surface 1D of the multilayer body 1, are connected to the second end-surface electrode 5. The second internal electrodes 3, which are led to the first side surface 1E of the multilayer body 1, are connected to the first side-surface electrode 6. The second internal electrodes 3, which are led to the second side surface 1F of the multilayer body 1, are connected to the second side-surface electrode 7.

For example, a power supply line or a signal line is cut at an intermediate portion thereof within a circuit, the first end-surface electrode 4 is connected to one division provided by the cutting, the second end-surface electrode 5 is connected to the other division provided by the cutting, and the first side-surface electrode 6 and the second side-surface electrode 7 are connected to a ground potential, so that the multilayer ceramic capacitor 100 can be used as a three-terminal capacitor. When doing so, the first internal electrodes 2 define through electrodes, and the second internal electrodes 3 define ground electrodes.

The first end-surface electrode 4 and the second end-surface electrode 5 have the same multilayer structure. Specifically, as depicted in FIG. 2, the first end-surface electrode 4 and the second end-surface electrode 5 each include a first base electrode layer 11 on outer surfaces of the multilayer body 1, a first plating electrode layer 21 on the outer surface of the first base electrode layer 11, and a second plating electrode layer 22 on the outer surface of the first plating electrode layer 21.

The first base electrode layers 11 may include any material as a main component, and Ni is used as the main component in present example embodiment. However, another metal such as Cu, Ag, Pd, or Au may also be used instead of Ni. Alternatively, an alloy of Ni and another metal or an alloy of Cu, Ag, Pd, Au, or the like and another metal may be used.

The first base electrode layers 11 may have any thickness dimension, and, for example, the portions thereof formed on the first main surface 1A or the second main surface 1B may have a thickness dimension of approximately 3.0 μm to 150.0 μm, for example. In present example embodiment, the thickness dimension of the portions of the first base electrode layers 11 on the first main surface 1A or the second main surface 1B is about 9.0 μm, for example.

The thickness dimension of the portions of the first base electrode layers 11 on the first main surface 1A or the second main surface 1B is determined using the following method. First, a completed multilayer ceramic capacitor 100 is prepared. Then, the multilayer ceramic capacitor 100 is cut at a portion thereof that corresponds to about ½ of the dimension in the width direction W, and a cross section parallel to the first side surface 1E and the second side surface 1F is observed. The first end-surface electrode 4 and the second end-surface electrode 5 are formed on the two ends of the cross section to have the shape of the alphabet character “C” (can also be said to be the shape of “ [symbol] ” of Japanese katakana characters). That is, the first end-surface electrode 4 is provided on the first main surface 1A, the first end surface 1C, and the second main surface 1B. The second end-surface electrode 5 is provided on the first main surface 1A, the second end surface 1D, and the second main surface 1B. Subsequently, the maximum dimension of the portion, of the first base electrode layer 11 of the first end-surface electrode 4, that is provided on the first main surface 1A, the maximum dimension of the portion, of the first base electrode layer 11 of the first end-surface electrode 4, that is provided on the second main surface 1B, the maximum dimension of the portion, of the first base electrode layer 11 of the second end-surface electrode 5, that is provided on the first main surface 1A, and the maximum dimension of the portion, of the first base electrode layer 11 of the second end-surface electrode 5, that is provided on the second main surface 1B are determined. Next, the average of the four maximum dimensions is determined and defined as the thickness dimension of the portions of the first base electrode layers 11 on the first main surface 1A or the second main surface 1B. The thickness dimension of the portions of the first plating electrode layers 21 on the first main surface 1A or the second main surface 1B and the thickness dimension of the portions of the second plating electrodes 22 on the first main surface 1A or the second main surface 1B are also determined using a similar method.

The first plating electrode layers 21 may include any material as a main component, and Ni is used as the main component in present example embodiment. The first plating electrode layers 21 function mainly to enhance the resistance to soldering heat and to enhance bondability.

The first plating electrode layers 21 may have any thickness dimension, and, for example, the portions thereof formed on the first main surface 1A or the second main surface 1B may have a thickness dimension of approximately 1.0 μm to 6.0 μm, for example. In present example embodiment, the thickness dimension of the portions of the first plating electrode layers 21 on the first main surface 1A or the second main surface 1B is about 3.0 μm, for example.

The second plating electrode layers 22 may include any material as a main component, and Sn is used as the main component in present example embodiment. The second plating electrode layers 22 function mainly to enhance solderability.

The second plating electrode layers 22 may have any thickness dimension, and, for example, the portions thereof formed on the first main surface 1A or the second main surface 1B may have a thickness dimension of approximately 1.5 μm to 6.0 μm, for example. In present example embodiment, the thickness dimension of the portions of the second plating electrode layers 22 on the first main surface 1A or the second main surface 1B is about 3.0 μm, for example.

As a result, the total thickness dimension of the portions, of the first plating electrode layer 21 and the second plating electrode layer 22 of each of the first end-surface electrode 4 and the second end-surface electrode 5, that are provided on the first main surface 1A or the second main surface 1B is approximately 2.5 μm to 12.0 μm, for example. In present example embodiment, the total thickness dimension of the portions, of the first plating electrode layer 21 and the second plating electrode layer 22 of each of the first end-surface electrode 4 and the second end-surface electrode 5, that are provided on the first main surface 1A or the second main surface 1B is about 6.0 μm, for example.

The first side-surface electrode 6 and the second end-surface electrode 7 have the same multilayer structure. Specifically, as depicted in FIG. 2, the first side-surface electrode 6 and the second side-surface electrode 7 each include a second base electrode layer 12 formed on outer surfaces of the multilayer body 1, a third plating electrode layer 23 formed on the outer surface of the second base electrode layer 12, a fourth plating electrode layer 24 formed on the outer surface of the third plating electrode layer 23, a fifth plating electrode layer 25 formed on the outer surface of the fourth plating electrode layer 24, and a sixth plating electrode layer 26 formed on the outer surface of the fifth plating electrode layer 25. Although FIG. 2 depicts the second side-surface electrode 7 and does not depict the first side-surface electrode 6, the first side-surface electrode 6 has the same structure as the second side-surface electrode 7.

The second base electrode layers 12 may include any material as a main component, and Ni is used as the main component in present example embodiment. However, another metal such as Cu, Ag, Pd, or Au may also be used instead of Ni. Alternatively, an alloy of Ni and another metal or an alloy of Cu, Ag, Pd, Au, or the like and another metal may be used.

The second base electrode layers 12 may have any thickness dimension, and, for example, the portions thereof formed on the first main surface 1A or the second main surface 1B may have a thickness dimension of approximately 3.0 μm to 150.0 μm. In present example embodiment, the thickness dimension of the portions of the second base electrode layers 12 on the first main surface 1A or the second main surface 1B is about 9.0 μm, for example.

The thickness dimension of the portions of the second base electrode layers 12 on the first main surface 1A or the second main surface 1B is determined using the following method. First, a completed multilayer ceramic capacitor 100 is prepared. Then, the multilayer ceramic capacitor 100 is cut at a portion thereof that corresponds to about ½ of the dimension in the lengthwise direction L, and a cross section parallel to the first end surface 1C and the second end surface 1D is observed. The first side-surface electrode 6 and the second side-surface electrode 7 are formed on the two sides of the cross section to have the shape of alphabet character “C” (can also be said to be the shape of “ [symbol] ” of Japanese katakana characters). That is, the first side-surface electrode 6 is provided on the first main surface 1A, the first side surface 1E, and the second main surface 1B. The second side-surface electrode 7 is provided on the first main surface 1A, the second side surface 1F, and the second main surface 1B.

Subsequently, the maximum dimension of the portion, of the second base electrode layer 12 of the first side-surface electrode 6, that is provided on the first main surface 1A, the maximum dimension of the portion, of the second base electrode layer 12 of the first side-surface electrode 6, that is provided on the second main surface 1B, the maximum dimension of the portion, of the second base electrode layer 12 of the second side-surface electrode 7, that is provided on the first main surface 1A, and the maximum dimension of the portion, of the second base electrode layer 12 of the second side-surface electrode 7, that is provided on the second main surface 1B are determined. Next, the average of the four maximum dimensions is determined and defined as the thickness dimension of the portions of the second base electrode layers 12 on the first main surface 1A or the second main surface 1B. The thickness dimension of the portions of the third plating electrode layers 23 on the first main surface 1A or the second main surface 1B, the thickness dimension of the portions of the fourth plating electrode layers 24 on the first main surface 1A or the second main surface 1B, the thickness dimension of the portions of the fifth plating electrode layers 25 on the first main surface 1A or the second main surface 1B, and the thickness dimension of the portions of the sixth plating electrode layers 26 on the first main surface 1A or the second main surface 1B are also determined using a similar method.

The third plating electrode layers 23 may include any material as a main component, and Ni is used as the main component in present example embodiment. The third plating electrode layers 23 function mainly to enhance bondability.

The third plating electrode layers 23 may have any thickness dimension, and, for example, the portions thereof formed on the first main surface 1A or the second main surface 1B may have a thickness dimension of approximately 1.0 μm to 6.0 μm. In present example embodiment, the thickness dimension of the portions of the third plating electrode layers 23 on the first main surface 1A or the second main surface 1B is about 3.0 μm, for example.

The fourth plating electrode layers 24 may include any material as a main component, and Sn is used as the main component in present example embodiment. The fourth plating electrode layers 24 are provided mainly to increase the thickness dimensions of the first side-surface electrode 6 and the second side-surface electrode 7. When the fourth plating electrode layers 24 include Sn as a material for a main component, stress transferred from a board to the multilayer body 1 of the multilayer ceramic capacitor 100 when the multilayer ceramic capacitor 100 is mounted on the board can be absorbed effectively by the fourth plating electrode layers 24 owing to Sn, which defines a soft material. This contributes to the reduction or prevention of cracks or chips in the multilayer body 1.

The fourth plating electrode layers 24 may have any thickness dimension, and, for example, the portions thereof formed on the first main surface 1A or the second main surface 1B may have a thickness dimension of approximately 30.0 μm to 50.0 μm. In present example embodiment, the thickness dimension of the portions of the first plating electrode layers 21 on the first main surface 1A or the second main surface 1B is about 40.0 μm, for example.

The fifth plating electrode layers 25 may include any material as a main component, and Ni is used as the main component in present example embodiment. The fifth plating electrode layers 25 function mainly to enhance the resistance to soldering heat and to enhance bondability.

The fifth plating electrode layers 25 may have any thickness dimension, and, for example, the portions thereof formed on the first main surface 1A or the second main surface 1B may have a thickness dimension of approximately 1.0 μm to 6.0 μm. In present example embodiment, the thickness dimension of the portions of the fifth plating electrode layers 25 on the first main surface 1A or the second main surface 1B is about 3.0 μm, for example.

The sixth plating electrode layers 26 may include any material as a main component, and Sn is used as the main component in present example embodiment. The sixth plating electrode layers 26 function mainly to enhance solderability.

The sixth plating electrode layers 26 may have any thickness dimension, and, for example, the portions thereof formed on the first main surface 1A or the second main surface 1B may have a thickness dimension of approximately 1.5 μm to 6.0 μm. In present example embodiment, the thickness dimension of the portions of the sixth plating electrode layers 26 on the first main surface 1A or the second main surface 1B is about 3.0 μm, for example.

As a result, the total thickness dimension of the portions, of the third plating electrode layer 23, the fourth plating electrode layer 24, the fifth plating electrode layer 25, and the sixth plating electrode layer 26 of each of the first side-surface electrode 6 and the second side-surface electrode 7, that are provided on the first main surface 1A or the second main surface 1B is approximately 33.5 μm to 68.0 μm, for example. In present example embodiment, the total thickness dimension of the portions, of the third plating electrode layer 23, the fourth plating electrode layer 24, the fifth plating electrode layer 25, and the sixth plating electrode layer 26 of each of the first end-surface electrode 4 and the second end-surface electrode 5, that are provided on the first main surface 1A or the second main surface 1B is about 49.0 μm, for example.

As described above, the total thickness dimension of the portions, of the first plating electrode layer 21 and the second plating electrode layer 22 of each of the first end-surface electrode 4 and the second end-surface electrode 5, that are provided on the first main surface 1A or the second main surface 1B is approximately 2.5 μm to 12.0 μm, for example. Meanwhile, the total thickness dimension of the portions, of the third plating electrode layer 23, the fourth plating electrode layer 24, the fifth plating electrode layer 25, and the sixth plating electrode layer 26 of each of the first side-surface electrode 6 and the second side-surface electrode 7, that are provided on the first main surface 1A or the second main surface 1B is approximately 33.5 μm to 68.0 μm, for example. Thus, assuming that the total thickness dimension of the portions of the third plating electrode layer, the fourth plating electrode layer, the fifth plating electrode layer, and the sixth plating electrode layer that are provided on the first main surface 1A or the second main surface 1B is equivalent to 100%, the total thickness dimension of the portions of the first plating electrode layer 21 and the second plating electrode layer 22 that are provided on the first main surface A is about 3.68% or greater and not greater than about 35.8%, i.e., approximately 3.6% or greater and approximately not greater than 36.0%, for example.

Table 1 presents the abovementioned relationships.

TABLE 1
Thickness dimensions of plating electrode layers

| First end-surface electrode 4, second end-surface | | First side-surface electrode 6, second side- | |
|---|---|---|---|
| electrode 5 | | surface electrode 7 | |
| — | — | Third plating | Approximately 1 to 6 μm |
| | | electrode layer 23 | |
| — | — | Fourth plating | Approximately 30 to 50 μm |
| | | electrode layer 24 | |
| First plating | Approximately 1 to 6 μm | Fifth plating | Approximately 1 to 6 μm |
| electrode layer 21 | | electrode layer 25 | |
| Second plating | Approximately 1.5 to 6 μm | Sixth plating | Approximately 1.5 to 6 μm |
| electrode layer 22 | | electrode layer 26 | |
| Total | Approximately 2.5 to 12 μm | Total | Approximately 33.5 to 68 μm |

(Total thickness dimension of plating electrode layers of each of first end-surface electrode 4 and second end-surface electrode 5)/(Total thickness dimension of plating electrode layers of each of first side-surface electrode 6 and second side-surface electrode 7) = Approximately 3.6% to 36.0%

In present example embodiment, as described above, the total thickness dimension of the portions, of the first plating electrode layer 21 and the second plating electrode layer 22 of each of the first end-surface electrode 4 and the second end-surface electrode 5, that are provided on the first main surface 1A or the second main surface 1B is about 6.0 μm, and the total thickness dimension of the portions, of the third plating electrode layer 23, the fourth plating electrode layer 24, the fifth plating electrode layer 25, and the sixth plating electrode layer 26 of each of the first side-surface electrode 6 and the second side-surface electrode 7, that are provided on the first main surface 1A or the second main surface 1B is about 49.0 μm, for example. Thus, assuming that the total thickness dimension of the portions of the third plating electrode layer 23, the fourth plating electrode layer 24, the fifth plating electrode layer 25, and the sixth plating electrode layer 26 that are provided on the first main surface 1A or the second main surface 1B is equivalent to 100%, the total thickness dimension of the portions of the first plating electrode layer 21 and the second plating electrode layer 22 that are provided on the first main surface A is approximately 12.2%, for example.

Assuming that the thickness dimension of the portions of the first base electrode layers 11 that are provided on the first main surface 1A or the second main surface 1B is the same as the thickness dimension of the portions of the second base electrode layers 12 that are provided on the first main surface 1A or the second main surface 1B, the thickness dimension of the portions of the first side-surface electrode 6 and the second side-surface electrode 7 that are provided on the first main surface 1A or the second main surface 1B is greater, by about 43.0 μm, for example, than the thickness dimension of the portions of the first end-surface electrode 4 and the second end-surface electrode 5 that are provided on the first main surface 1A or the second main surface 1B.

Mounting Structure 200 with Multilayer Ceramic Capacitor 100

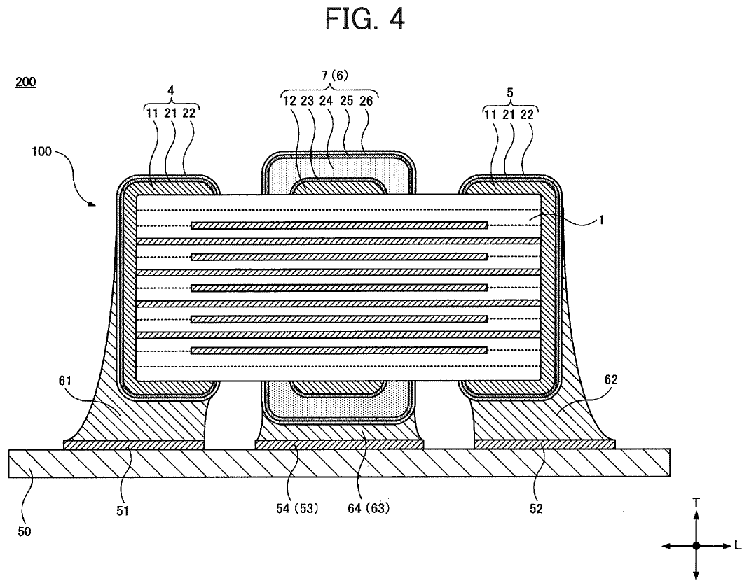

As an example of the mounting structure, FIG. 4 depicts a mounting structure 200 implemented by mounting the multilayer ceramic capacitor 100 on a board 50. FIG. 4 is an explanatory view (cross-sectional view) of a mounting structure 200.

A first land electrode 51, a second land electrode 52, a third land electrode 53, and a fourth land electrode 54 are provided on a main surface of the board 50. The first end-surface electrode 4 of the multilayer ceramic capacitor 100 is bonded to the first land electrode 51 by solder 61, the second end-surface electrode 5 is bonded to the second land electrode 52 by solder 62, the first side-surface electrode 6 is bonded to the third land electrode 53 by solder 63, and the second side-surface electrode 7 is bonded to the fourth land electrode 54 by solder 64. Although FIG. 4 does not show the site where the second side-surface electrode 7 is bonded to the fourth land electrode 54 by the solder 64, this site has a similar structure to the site where the first side-surface electrode 6 is bonded to the third land electrode 53 by the solder 63.

The solder 61, the solder 62, the solder 63, and the solder 64 are respectively provided through a process in which solder pastes supplied in advance on the first land electrode 51, the second land electrode 52, the third land electrode 53, and the fourth land electrode 54 prior to the production of the mounting structure 200 are molten by reflow and are then cooled and thus resolidified. The solder 61, the solder 62, the solder 63, and the solder 64 each form a solder fillet at a bonding site.

The solder 61, the solder 62, the solder 63, and the solder 64 are an example of the bonding material. However, the bonding material may include any material, which is not limited to solder, and may include another material such as an electrically conductive resin.

In present example embodiment, as described above, the thickness dimension of the portions of the first side-surface electrode 6 and the second side-surface electrode 7 that are provided on the first main surface 1A or the second main surface 1B is greater, by about 43.0 μm, for example, than the thickness dimension of the portions of the first end-surface electrode 4 and the second end-surface electrode 5 that are provided on the first main surface 1A or the second main surface 1B. Thus, the thickness dimension of the solder 61 between the first land electrode 51 and the first end-surface electrode 4 and the thickness dimension of the solder 62 between the second land electrode 52 and the second end-surface electrode 5 are each greater, by about 43.0 μm, for example, than the thickness dimension of the solder 63 between the third land electrode 53 and the first side-surface electrode 6 and the thickness dimension of the solder 64 between the fourth land electrode 54 and the second side-surface electrode 7.

In the mounting structure 200 with the multilayer ceramic capacitor 100, the solder 61 between the first land electrode 51 and the first end-surface electrode 4 and the solder 62 between the second land electrode 52 and the second end-surface electrode 5 each have a great thickness dimension, thus reducing or preventing cracks or chips in the portion of the ceramic multilayer body 1 on which the first end-surface electrode 4 is formed, the vicinity of this portion, the portion of the multilayer body 1 on which the second end-surface electrode 5 is formed, and the vicinity of this portion, even when stress is applied to the board 50 and thus the board 50 is flexed. In particular, the solder 61 and the solder 62 having a great thickness dimension absorb stress transferred from the board 50 and decrease stress transferred to the multilayer body 1, thus reducing or preventing cracks or chips in the portion of the multilayer body 1 on which the first end-surface electrode 4 is formed, the vicinity of this portion, the portion of the multilayer body 1 on which the second end-surface electrode 5 is formed, and the vicinity of this portion.

With respect to the mounting structure 200, it may be considered that the multilayer ceramic capacitor 100 is supported on the board 50 mainly by the first side-surface electrode 6 and the second side-surface electrode 7, and the first end-surface electrode 4 and the second end-surface electrode 5 are in a floating state.

### Experiment 1

The following experiment was performed in order to confirm the effectiveness of example embodiments of the present invention. First, 10 multilayer ceramic capacitors according to example 1, 10 multilayer ceramic capacitors according to example 2, and 10 multilayer ceramic capacitors according to comparative example 1 were produced. The following describes the structures, dimensions, and the like in example 1, example 2, and comparative example 1 by referring to the cross-sectional view of the multilayer ceramic capacitor 100 in FIG. 2.

In all of the multilayer ceramic capacitors in example 1, example 2, and comparative example 1, the thickness dimension of the portions, on the first main surface 1A or the second main surface 1B, of the first plating electrode layers 21 of the first end-surface electrode 4 and the second end-surface electrode 5 was 3.0 μm, and the thickness dimension of the portions, on the first main surface 1A or the second main surface 1B, of the second plating electrode layers 22 of the first end-surface electrode 4 and the second end-surface electrode 5 was 3.0 μm.

In the multilayer ceramic capacitors in example 1, the thickness dimensions of the portions, on the first main surface 1A or the second main surface 1B, of the third plating electrode layers 23, the fourth plating electrode layers 24, the fifth plating electrode layers 25, and the sixth plating electrode layers 26 of the first side-surface electrode 6 and the second side-surface electrode 7 were respectively 3.0 μm, 30.0 μm, 3.0 μm, and 3.0 μm.

In the multilayer ceramic capacitors in example 2, the thickness dimensions of the portions, on the first main surface 1A or the second main surface 1B, of the third plating electrode layers 23, the fourth plating electrode layers 24, the fifth plating electrode layers 25, and the sixth plating electrode layers 26 of the first side-surface electrode 6 and the second side-surface electrode 7 were respectively 3.0 μm, 50.0 μm, 3.0 μm, and 3.0 μm.

In the multilayer ceramic capacitors in comparative example 1, the thickness dimensions of the portions, on the first main surface 1A or the second main surface 1B, of the third plating electrode layers 23, the fourth plating electrode layers 24, the fifth plating electrode layers 25, and the sixth plating electrode layers 26 of the first side-surface electrode 6 and the second side-surface electrode 7 were respectively 0 μm, 0 μm, 3.0 μm, and 3.0 μm. That is, none of the third plating electrode layers 23 and the fourth plating electrode layers 24 were formed on the multilayer ceramic capacitors in comparative example 1.

The 10 multilayer ceramic capacitors in each of example 1, example 2, and comparative example 1 were each mounted on a board having a longitudinal dimension of 4 cm and a lateral dimension of 10 cm.

The 30 boards each mounted with a multilayer ceramic capacitor were sequentially subjected to a flex resistance experiment. Specifically, two opposed edges (shorter edges) of the board were fixed, and with a pressure application rod abutting the central portion of the back side of the board, the board was flexed by pressing the pressure application rod against the board sequentially by 1.0 mm, 2.0 mm, 3.0 mm, 4.0 mm, 5.0 mm, 6.0 mm, and 7.0 mm. Then, cracks or chips produced in the multilayer body 1 of the multilayer ceramic capacitor were observed. Note that the amount by which the pressure application rod is pressed is the flexure amount of the board herein.

Table 2 indicates the results of the experiment. The numbers in fields indicate the cumulative number of samples in which a crack or a chip was produced, from among the 10 samples.

TABLE 2
Cumulative number of samples in which crack or chip is produced (Cumulative total from among 10 samples in
each example)

| Thickness dimension of each plating electrode | | | | | | | | |
|---|---|---|---|---|---|---|---|---|
| layer of first side-surface electrode 6 and | | Flexure amount | | | | | | |
| second side-surface electrode 7 | | 1.0 mm | 2.0 mm | 3.0 mm | 4.0 mm | 5.0 mm | 6.0 mm | 7.0 mm |
| Comparative | Thickness of third plating | 0 | 4 | 6 | 8 | 9 | 10 | — |
| Example 1 | electrode layers 23: 0 μm | | | | | | | |
| | Thickness of fourth plating | | | | | | | |
| | electrode layers 24: 0 μm | | | | | | | |
| | Thickness of fifth plating | | | | | | | |
| | electrode layers 25: 3 μm | | | | | | | |
| | Thickness of sixth plating | | | | | | | |
| | electrode layers 26: 3 μm | | | | | | | |
| Example 1 | Thickness of third plating | 0 | 0 | 0 | 0 | 1 | 2 | 6 |
| | electrode layers 23: 3 μm | | | | | | | |
| | Thickness of fourth plating | | | | | | | |
| | electrode layers 24: 30 μm | | | | | | | |
| | Thickness of fifth plating | | | | | | | |
| | electrode layers 25: 3 μm | | | | | | | |
| | Thickness of sixth plating | | | | | | | |
| | electrode layers 26: 3 μm | | | | | | | |
| Example 2 | Thickness of third plating | 0 | 0 | 0 | 0 | 0 | 0 | 2 |
| | electrode layers 23: 3 μm | | | | | | | |
| | Thickness of fourth plating | | | | | | | |
| | electrode layers 24: 50 μm | | | | | | | |
| | Thickness of fifth plating | | | | | | | |
| | electrode layers 25: 3 μm | | | | | | | |
| | Thickness of sixth plating | | | | | | | |
| | electrode layers 26: 3 μm | | | | | | | |

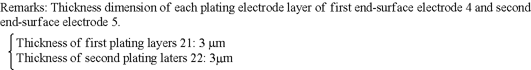

As seen in table 2, a crack or a chip was produced in four of the multilayer ceramic capacitors in comparative example 1 at a flexure amount of 2.0 mm, then the cumulative total number increased with increase in the flexure amount, and a crack or a chip was produced in all of the 10 samples at a flexure amount of 6.0 mm. With respect to the multilayer ceramic capacitors in example 1, in which the thickness dimension of the fourth plating electrode layers 24 was 30.0 μm, by contrast, a crack or a chip was produced in one of the samples at a flexure amount of 5.0 mm, and the cumulative total number of samples in which a crack or a chip was produced was only two at a flexure amount of 6.0 mm and was only six at a flexure amount of 7.0 mm. With respect to the multilayer ceramic capacitors in example 2, in which the thickness dimension of the fourth plating electrode layers 24 was 50.0 μm, a crack or a chip was produced in two of the samples at a flexure amount of 7.0 mm, while a crack or a chip was not produced in the remaining eight. Accordingly, the effectiveness of the present invention was confirmed. Note that increasing the thickness dimension of the fourth plating electrode layers 24 is considered to increase the effect of reducing or preventing cracks and chips.

### First Manufacturing Method for Multilayer Ceramic Capacitor 100

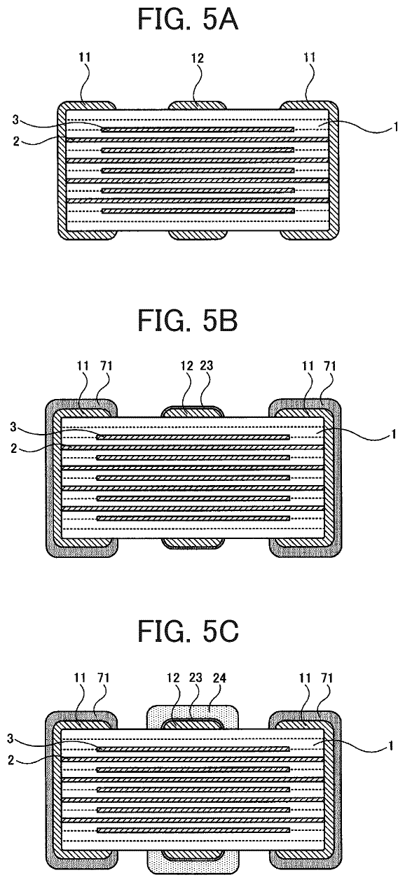

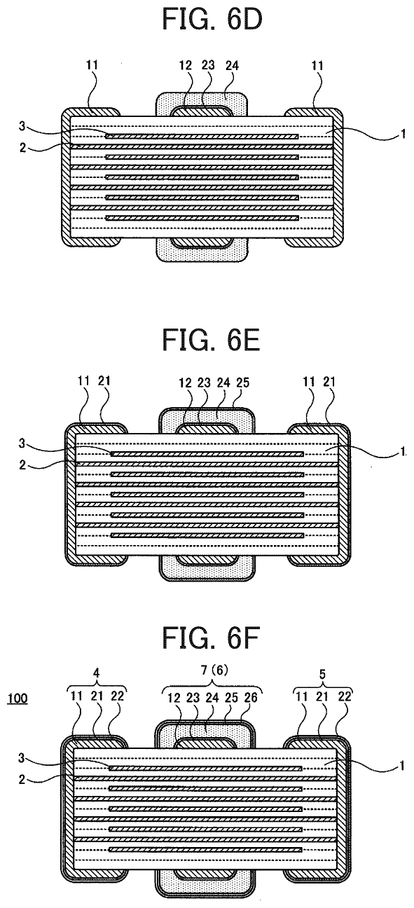

For example, the multilayer ceramic capacitor 100 can be manufactured using a first manufacturing method indicated in FIGS. 5A to 6F. On an actual manufacturing line, as a general rule, mother ceramic green sheets would be produced and used, and, in the middle of the process, mother unfired multilayer bodies would be cut into individual unfired multilayer bodies, thereby collectively manufacturing a multitude of multilayer ceramic capacitors 100. For the sake of description, however, descriptions are given herein of situations in which one multilayer ceramic capacitor 100 is manufactured.

First, a multilayer body 1 depicted in FIG. 5A is produced that has first internal electrodes 2 and second internal electrodes 3 formed therein and also has first base electrode layers 11 and second base electrode layers 12 formed at prescribed positions on the outer surfaces thereof.

Specifically, first, dielectric ceramics powder, a binder resin, a solvent, and the like are prepared and subjected to wet blending so as to produce ceramic slurry.

Then, the ceramic slurry is applied to carrier films so as to be shaped like sheets by using, for example, a die coater, a gravure coater, or a micro-gravure coater, and is dried, thereby producing ceramic green sheets.

Next, in order to form the first internal electrodes 2 and the second internal electrodes 3, an electrically conductive paste prepared in advance is applied to (e.g., printed on) main surfaces of prescribed ceramic green sheets so as to achieve desired pattern shapes. In the meantime, the electrically conductive paste is not applied to ceramic green sheets for constituting outer layers. For example, a mixture of a solvent, a binder resin, metal powder (e.g., Ni powder), and the like may be used for the electrically conductive paste.

Subsequently, the ceramic green sheets are stacked in a prescribed order and subjected to thermocompression bonding so as to be integrated, thereby producing an unfired multilayer body.

Next, in order to form the first base electrode layers 11 and the second base electrode layers 12 on the unfired multilayer body, an electrically conductive paste prepared in advance is applied to the outer surfaces of the unfired multilayer body so as to achieve desired shapes and thicknesses. For example, a mixture of a solvent, a binder resin, metal powder, ceramics powder, and the like may be used for the electrically conductive paste.

Thereafter, the unfired multilayer body is fired with a prescribed profile so as to provide a completed multilayer body 1. In this case, the ceramic green sheets are fired and thus define ceramic layers 1a, the electrically conductive paste applied to the main surfaces of the ceramic green sheets is concurrently fired and thus defines first internal electrodes 2 and second internal electrodes 3, and the electrically conductive paste applied to the outer surfaces of the unfired multilayer body is concurrently fired and thus defines first base electrode layers 11 and second base electrode layers 12.

In this manufacturing method, the producing of the multilayer body 1 and the forming of the first base electrode layers 11 and the second base electrode layers 12 are concurrently performed through concurrent firing. However, the multilayer body 1 may first be produced by firing, and then the electrically conductive paste may be applied to the outer surfaces of the multilayer body 1 and fired so as to form the first base electrode layers 11 and the second base electrode layers 12.

Next, as depicted in FIG. 5B, with the first base electrode layers 11 being covered with masks 71, third plating electrode layers 23 are formed on the second base electrode layers 12.

Subsequently, as depicted in FIG. 5C, with the first base electrode layers 11 being covered with the masks 71, fourth plating electrode layers 24 are formed on the third plating electrode layers 23.

Thereafter, as depicted in FIG. 6D, the masks 71 are removed from the first base electrode layers 11.

Subsequently, as depicted in FIG. 6E, first plating electrode layers 21 on the first base electrode layers 11 and fifth plating electrode layers 25 on the fourth plating electrode layers 24 are concurrently formed.

Thereafter, as depicted in FIG. 6F, second plating electrode layers 22 on the first plating electrode layers 21 and sixth plating electrode layers 26 on the fifth plating electrode layers 25 are concurrently formed. As a result, a first end-surface electrode 4, a second end-surface electrode 5, a first side-surface electrode 6, and a second side-surface electrode 7 are formed at prescribed positions on the outer surfaces of the multilayer body 1, thereby providing a completed multilayer ceramic capacitor 100.

### Second Manufacturing Method for Multilayer Ceramic Capacitor 100

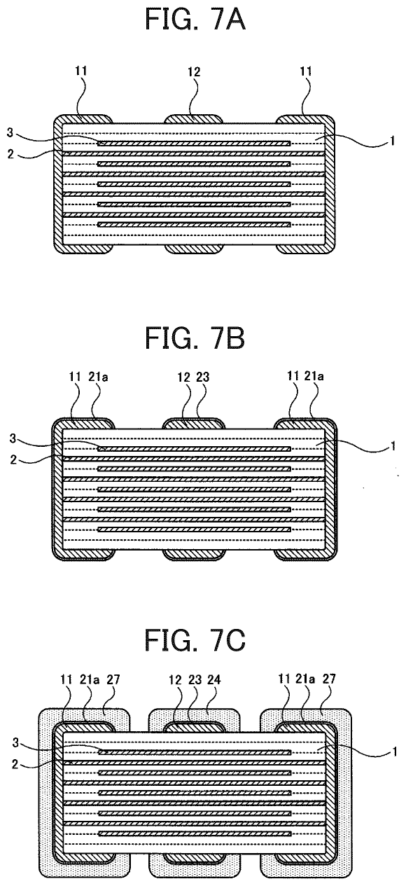

The multilayer ceramic capacitor 100 can also be manufactured using a second manufacturing method indicated in FIGS. 7A to 9G.

First, a multilayer body 1 depicted in FIG. 7A is produced using the same method as the first manufacturing method described above, the multilayer body 1 having first internal electrodes 2 and second internal electrodes 3 formed therein and also having first base electrode layers 11 and second base electrode layers 12 formed at prescribed positions on the outer surfaces thereof.

Then, as depicted in FIG. 7B, portions 21a for first plating electrode layers 21 are formed on the first base electrode layers 11 concurrently with forming third plating electrode layers 23 on the second base electrode layers 12.

Next, as depicted in FIG. 7C, seventh plating electrode layers 27 on the portions 21a for first plating electrode layers 21 and fourth plating electrode layers 24 on the third plating electrode layers 23 are concurrently formed.

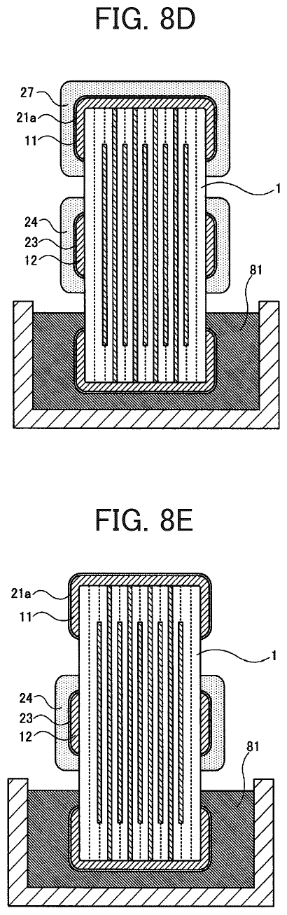

Subsequently, as depicted in FIG. 8D, one end portion of the multilayer body 1 is soaked in a solvent 81, and the seventh plating electrode layer 27 on the one end portion of the multilayer body 1 is stripped and removed such that the portion 21a for a first plating electrode layer 21 is exposed on the one end portion of the multilayer body 1.

Afterward, as depicted in FIG. 8E, the other end portion of the multilayer body 1 is soaked in the solvent 81, and the seventh plating electrode layer 27 on the other end portion of the multilayer body 1 is stripped and removed such that the portion 21a for a first plating electrode layer 21 is exposed on the other end portion of the multilayer body 1.

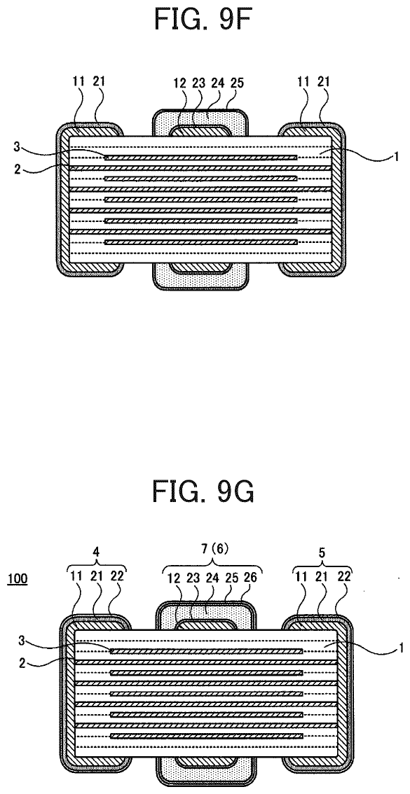

Next, as depicted in FIG. 9F, the portions 21a for first plating electrode layers 21 are subjected to plating growth so as to provide completed plating first electrode layers 21, concurrently with forming fifth plating electrode layers 25 on the fourth plating electrode layers 24. Note that the thickness dimension of the first plating electrode layers 21 is greater in the second manufacturing method than in the first manufacturing method.

Thereafter, as depicted in FIG. 9G, second plating electrode layers 22 on the first plating electrode layers 21 and sixth plating electrode layers 26 on the fifth plating electrode layers 25 are concurrently formed. As a result, a first end-surface electrode 4, a second end-surface electrode 5, a first side-surface electrode 6, and a second side-surface electrode 7 are formed at prescribed positions on the outer surfaces of the multilayer body 1, thereby providing a completed multilayer ceramic capacitor 100.

Descriptions have been given of the multilayer ceramic capacitor 100 and the mounting structure 200 according to example embodiments. However, the present invention is not limited to the features described above, and can have various changes made therein without departing from the spirit of the present invention.

For example, the material for the multilayer body 1, the material for the main component of the first internal electrodes 2 and the second internal electrodes 3, the material for the main component of the first base electrode layers 11 and the second base electrode layers 12, the material for the main component of the first plating electrode layers 21, the second plating electrode layers 22, the third plating electrode layers 23, the fourth plating electrode layers 24, the fifth plating electrode layers 25, and the sixth plating electrode layers 26, and the like are all exemplary, and every material can be replaced with another.

Although the first side-surface electrodes 6 and the second side-surface electrodes 7 are separate bodies in the example embodiments described above, the first side-surface electrode 6 and the second side-surface electrode 7 can be connected on at least one of the first main surface 1A or the second main surface 1B of the multilayer body 1 so as to be integrated.

Note that a multilayer ceramic capacitor according to an example embodiment of the present invention is consistent with the descriptions above.

With respect to a multilayer ceramic capacitor according to an example embodiment of the present invention, it is preferable that the first and fifth plating electrode layers include the same material, and the second and sixth plating electrode layers include the same material. When doing so, the first and fifth plating electrode layers can be concurrently formed, and the second and sixth plating electrode layers can be concurrently formed, thereby enhancing the production efficiency for the multilayer ceramic capacitor.

It is preferable that the third plating electrode layers include the same material as the first and fifth plating electrode layers, and the fourth plating electrode layers include the same material as the second and sixth plating electrode layers. When doing so, only two types of plating electrode baths need to be prepared, thereby enhancing the production efficiency for the multilayer ceramic capacitor.

It is also preferable that a main component of the first and fifth plating electrode layers is Ni; and a main component of the second and sixth plating electrode layers is Sn. In this case, the first and fifth plating electrode layers can function mainly to enhance resistance to soldering heat and enhance bondability, and the second and sixth plating electrode layers can function mainly to enhance solderability.

It is also preferable that a main component of the first, third, and fifth plating electrode layers is Ni, and a main component of the second, fourth, and sixth plating electrode layers is Sn. When doing so, only two types of plating electrode baths need to be prepared, thereby enhancing the production efficiency for the multilayer ceramic capacitor.

The total thickness dimension of the portions of the third, fourth, fifth, and sixth plating electrode layers that are provided on the first or second main surface is preferably greater than the total thickness dimension of the portions of the first and second plating electrode layers that are provided on the first or second main surface. In this case, when the multilayer ceramic capacitor is mounted on, for example, a board, solder having a sufficiently large thickness dimension is formed directly under each of the first and second end-surface electrodes, thus appropriately reducing or preventing cracks or chips in the multilayer body even when stress is applied to the board and thus a flexure (or torsional deformation) or the like is produced in the board.

Assuming that the total thickness dimension of the portions of the third, fourth, fifth, and sixth plating electrode layers that are provided on the first or second main surface is equivalent to 100%, it is also preferable that the total thickness dimension of the portions of the first and second plating electrode layers that are provided on the first or second main surface is about 3.6% or greater and not greater than about 36.0%, for example. As long as the value falls within this range, when the multilayer ceramic capacitor is mounted on, for example, a board, cracks or chips in the multilayer body can be appropriately reduced or prevented even when stress is applied to the board and thus a flexure or the like is produced in the board.

It is also preferable that the total thickness dimension of the portions of the third, fourth, fifth, and sixth plating electrode layers that are provided on the first or second main surface is about 33.5 μm or greater and not greater than about 68.0 μm, for example, and the total thickness dimension of the portions of the first and second plating electrode layers that are provided on the first or second main surface is about 2.5 μm or greater and not greater than about 12.0 μm, for example. As long as the values fall within these ranges, when the multilayer ceramic capacitor is mounted on, for example, a board, cracks or chips in the multilayer body can be appropriately reduced or prevented even when stress is applied to the board and thus a flexure or the like is produced in the board.

With respect to the specific thickness dimension of each plating electrode layer, it is also preferable that the thickness dimension of the portions of the third plating electrode layers that are provided on the first or second main surface is about 1.0 μm or greater and not greater than about 6.0 μm, for example, the thickness dimension of the portions of the fourth plating electrode layers that are provided on the first or second main surface is about 30.0 μm or greater and not greater than about 50.0 μm, for example, the thickness dimension of the portions of the first and fifth plating electrode layers that are provided on the first or second main surface is about 1.0 μm or greater and not greater than about 6.0 μm, for example, and the thickness dimension of the portions of the second and sixth plating electrode layers that are provided on the first or second main surface is about 1.5 μm or greater and not greater than about 6.0 μm, for example. As long as the values fall within these ranges, each of the plating electrode layers can achieve necessary and sufficient functions.

It is also preferable that the thickness dimension of the portions of the first and second base electrode layers that are provided on the first or second main surface is about 3.0 μm or greater and not greater than about 150.0 μm, for example. As long as the values fall within these ranges, each of the base electrode layers can achieve necessary and sufficient functions.

It is also preferable that the first and second side-surface electrodes are connected to each other on at least one of the first and second main surfaces. Also in this case, the multilayer ceramic capacitor defines and functions as a three-terminal capacitor.

For example, a multilayer ceramic capacitor according to an example embodiment of the present invention can be manufactured using a manufacturing method including producing the multilayer body; forming, on the multilayer body, the first base electrode layer of the first end-surface electrode, the first base electrode layer of the second end-surface electrode, the second base electrode layer of the first side-surface electrode, and the second base electrode layer of the second side-surface electrode; forming the third plating electrode layer on the second base electrode layer, forming the fourth plating electrode layer on the third plating electrode layer, forming the first plating electrode layer on the first base electrode layer, and forming the fifth plating electrode layer on the fourth plating electrode layer, and forming the second plating electrode layer on the first plating electrode layer, and forming the sixth plating electrode layer on the fifth plating electrode layer.

For example, a multilayer ceramic capacitor according to an example embodiment of the present invention can also be manufactured using an example manufacturing method including producing the multilayer body; forming, on the multilayer body, the first base electrode layer of the first end-surface electrode, the first base electrode layer of the second end-surface electrode, the second base electrode layer of the first side-surface electrode, and the second base electrode layer of the second side-surface electrode; forming a portion of the first plating electrode layer on the first base electrode layer, and forming the third plating electrode layer on the second base electrode layer, forming a seventh plating electrode layer on the portion of the first plating electrode layer, and forming the fourth plating electrode layer on the third plating electrode layer; stripping and removing the seventh plating electrode layer so as to expose the portion of the first plating electrode layer; completing the first plating electrode layer by subjecting the portion of the first plating electrode layer to plating growth so as to increase a thickness dimension, and forming the fifth plating electrode layer on the fourth plating electrode layer; and forming the second plating electrode layer on the first plating electrode layer, and forming the sixth plating electrode layer on the fifth plating electrode layer.

In these multilayer-ceramic-capacitor manufacturing methods, it is also preferable that the producing the multilayer body is performed concurrently with the step of forming the first base electrode layer of the first end-surface electrode, the first base electrode layer of the second end-surface electrode, the second base electrode layer of the first side-surface electrode, and the second base electrode layer of the second side-surface electrode. When doing so, the production efficiency for the multilayer ceramic capacitor is enhanced.

Note that a multilayer-ceramic-capacitor mounting structure according to one example embodiment of the present invention is consistent with the above descriptions.

In the multilayer-ceramic-capacitor mounting structure, for example, solder can be used as a bonding material.

In the multilayer-ceramic-capacitor mounting structure, it is also preferable that the third and fourth land electrodes are one integrated land electrode. The third and fourth land electrodes are both at a ground potential and thus can be integrated.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer body ceramic capacitor comprising:
a multilayer body including a plurality of ceramic layers, a plurality of first internal electrodes, and a plurality of second internal electrodes stacked in a height direction, a first main surface and a second main surface opposed to each other in the height direction, a first end surface and a second end surface opposed to each other in a lengthwise direction orthogonal to the height direction, and a first side surface and a second side surface opposed to each other in a width direction orthogonal to the height direction and the lengthwise direction;
a first end-surface electrode on the first end surface and extending from the first end surface so as to cover portions of the first main surface, the second main surface, the first side surface, and the second side surface;
a second end-surface electrode on the second end surface and extending from the second end surface so as to cover portions of the first main surface, the second main surface, the first side surface, and the second side surface;
a first side-surface electrode on the first side surface and extending from the first side surface so as to cover portions of the first main surface and the second main surface; and
a second side-surface electrode on the second side surface and extending from the second side surface so as to cover portions of the first main surface and the second main surface;
the first internal electrodes being connected to the first end-surface electrode and the second end-surface electrode;
the second internal electrodes being connected to the first side-surface electrode and the second side-surface electrode;
wherein the first end-surface electrode and the second end-surface electrode each include a first base electrode layer, a first plating electrode layer on the first base electrode layer, and a second plating electrode layer on the first plating electrode layer; and
the first side-surface electrode and the second side-surface electrode each include a second base electrode layer, a third plating electrode layer on the second base electrode layer, a fourth plating electrode layer on the third plating electrode layer, a fifth plating electrode layer on the fourth plating electrode layer, and a sixth plating electrode layer on the fifth plating electrode layer.

2. The multilayer ceramic capacitor according to claim 1, wherein
the first plating electrode layer and the fifth plating electrode layer include a same material; and
the second plating electrode layer and the sixth plating electrode layer include a same material.

3. The multilayer ceramic capacitor according to claim 2, wherein
the third plating electrode layer includes a same material as the first plating electrode layer and the fifth plating electrode layer; and
the fourth plating electrode layer includes a same material as the second plating electrode layer and the sixth plating electrode layer.

4. The multilayer ceramic capacitor according to claim 2, wherein
a main component of the first plating electrode layer and the fifth plating electrode layer is Ni; and
a main component of the second plating electrode layer and the sixth plating electrode layer is Sn.

5. The multilayer ceramic capacitor according to claim 3, wherein
a main component of the first plating electrode layer, the third plating electrode layer, and the fifth plating electrode layer is Ni; and
a main component of the second plating electrode layer, the fourth plating electrode layer, and the sixth plating electrode layer is Sn.

6. The multilayer ceramic capacitor according to claim 1, wherein a total thickness dimension of portions of the third plating electrode layer, the fourth plating electrode layer, the fifth plating electrode layer, and the sixth plating electrode layer that are provided on the first main surface or the second main surface is greater than a total thickness dimension of portions of the first plating electrode layer and the second plating electrode layer that are provided on the first main surface or the second main surface.

7. The multilayer ceramic capacitor according to claim 6, wherein assuming that the total thickness dimension of the portions of the third plating electrode layer, the fourth plating electrode layer, the fifth plating electrode layer, and the sixth plating electrode layer that are provided on the first main surface or the second main surface is equivalent to 100%, the total thickness dimension of the portions of the first plating electrode layer and the second plating electrode layer that are provided on the first main surface or the second main surface is about 3.6% or greater and not greater than about 36.0%.

8. The multilayer ceramic capacitor according to claim 6, wherein
the total thickness dimension of the portions of the third plating electrode layer, the fourth plating electrode layer, the fifth plating electrode layer, and the sixth plating electrode layer that are provided on the first main surface or the second main surface is about 33.5 μm or greater and not greater than about 68.0 μm; and
the total thickness dimension of the portions of the first plating electrode layer and the second plating electrode layer that are provided on the first main surface or the second main surface is about 2.5 μm or greater and not greater than about 12.0 μm.

9. The multilayer ceramic capacitor according to claim 8, wherein
a thickness dimension of the portion of the third plating electrode layer that is provided on the first main surface or the second main surface is about 1.0 μm or greater and not greater than about 6.0 μm;
a thickness dimension of the portion of the fourth plating electrode layer that is provided on the first main surface or the second main surface is about 30.0 μm or greater and not greater than about 50.0 μm;
thickness dimensions of the portions of the first plating electrode layer and the fifth plating electrode layer that are provided on the first main surface or the second main surface are each about 1.0 μm or greater and not greater than about 6.0 μm; and
thickness dimensions of the portions of the second plating electrode layer and the sixth plating electrode layer that are provided on the first main surface or the second main surface are each about 1.5 μm or greater and not greater than about 6.0 μm.

10. The multilayer ceramic capacitor according to claim 1, wherein thickness dimensions of portions of the first base electrode layer and the second base electrode layer that are provided on the first main surface or the second main surface are each about 3.0 μm or greater and not greater than about 150.0 μm.

11. The multilayer ceramic capacitor according to claim 1, wherein the first side-surface electrode and the second side-surface electrode are connected to each other on at least one of the first main surface or the second main surface.

12. A multilayer-ceramic-capacitor manufacturing method for manufacturing the multilayer ceramic capacitor according to claim 1, the multilayer-ceramic-capacitor manufacturing method comprising:
producing the multilayer body;
forming, on the multilayer body, the first base electrode layer of the first end-surface electrode, the first base electrode layer of the second end-surface electrode, the second base electrode layer of the first side-surface electrode, and the second base electrode layer of the second side-surface electrode;
forming the third plating electrode layer on the second base electrode layer;
forming the fourth plating electrode layer on the third plating electrode layer;
forming the first plating electrode layer on the first base electrode layer, and forming the fifth plating electrode layer on the fourth plating electrode layer; and
forming the second plating electrode layer on the first plating electrode layer, and forming the sixth plating electrode layer on the fifth plating electrode layer.

13. The multilayer-ceramic-capacitor manufacturing method according to claim 12, wherein the producing the multilayer body is performed concurrently with the forming the first base electrode layer of the first end-surface electrode, the first base electrode layer of the second end-surface electrode, the second base electrode layer of the first side-surface electrode, and the second base electrode layer of the second side-surface electrode.

14. A multilayer-ceramic-capacitor manufacturing method for manufacturing the multilayer ceramic capacitor according to claim 1, the multilayer-ceramic-capacitor manufacturing method comprising:
producing the multilayer body;
forming, on the multilayer body, the first base electrode layer of the first end-surface electrode, the first base electrode layer of the second end-surface electrode, the second base electrode layer of the first side-surface electrode, and the second base electrode layer of the second side-surface electrode;
forming a portion of the first plating electrode layer on the first base electrode layer, and forming the third plating electrode layer on the second base electrode layer;
forming a seventh plating electrode layer on the portion of the first plating electrode layer, and forming the fourth plating electrode layer on the third plating electrode layer;
stripping and removing the seventh plating electrode layer so as to expose the portion of the first plating electrode layer;
completing the first plating electrode layer by subjecting the portion of the first plating electrode layer to plating growth so as to increase a thickness dimension, and forming the fifth plating electrode layer on the fourth plating electrode layer; and
forming the second plating electrode layer on the first plating electrode layer, and forming the sixth plating electrode layer on the fifth plating electrode layer.

15. The multilayer-ceramic-capacitor manufacturing method according to claim 14, wherein the producing the multilayer body is performed concurrently with the forming the first base electrode layer of the first end-surface electrode, the first base electrode layer of the second end-surface electrode, the second base electrode layer of the first side-surface electrode, and the second base electrode layer of the second side-surface electrode.

16. A multilayer-ceramic-capacitor mounting structure comprising:
a board; and
a multilayer ceramic capacitor mounted on the board;
wherein
the multilayer ceramic capacitor includes:
a multilayer body including a plurality of ceramic layers, a plurality of first internal electrodes, and a plurality of second internal electrodes stacked in a height direction, a first main surface and a second main surface opposed to each other in the height direction, a first end surface and a second end surface opposed to each other in a lengthwise direction orthogonal to the height direction, and a first side surface and a second side surface opposed to each other in a width direction orthogonal to the height direction and the lengthwise direction;
a first end-surface electrode that is on the first end surface and extends from the first end surface so as to cover portions of the first main surface, the second main surface, the first side surface, and the second side surface;
a second end-surface electrode that is on the second end surface and extends from the second end surface so as to cover portions of the first main surface, the second main surface, the first side surface, and the second side surface;
a first side-surface electrode that is on the first side surface and extends from the first side surface so as to cover portions of the first main surface and the second main surface; and
a second side-surface electrode that is on the second side surface and extends from the second side surface so as to cover portions of the first main surface and the second main surface;
the first internal electrodes are connected to the first end-surface electrode and the second end-surface electrode;
the second internal electrodes are connected to the first side-surface electrode and the second side-surface electrode;
the first end-surface electrode and the second end-surface electrode each include a first base electrode layer and a first plating electrode layer on the first base electrode layer, and the first side-surface electrode and the second side-surface electrode each include a second base electrode layer, a third plating electrode layer on the second base electrode layer, a fourth plating electrode layer on the third plating electrode layer, and a fifth plating electrode layer on the fourth plating electrode layer;
the board includes:
a main surface on which a first land electrode, a second land electrode, a third land electrode, and a fourth land electrode are provided;
the first end-surface electrode, the second end-surface electrode, the first side-surface electrode, and the second side-surface electrode are respectively bonded to the first land electrode, the second land electrode, the third land electrode, and the fourth land electrode with a bonding material; and
a thickness dimension of the bonding material present between the first end-surface electrode and the first land electrode and a thickness dimension of the bonding material present between the second end-surface electrode and the second land electrode are each greater than a thickness dimension of the bonding material present between the first side-surface electrode and the third land electrode and a thickness dimension of the bonding material present between the second side-surface electrode and the fourth land electrode.

17. The multilayer-ceramic-capacitor mounting structure according to claim 16, wherein the bonding material is solder.

18. The multilayer-ceramic-capacitor mounting structure according to claim 16, wherein the third land electrode and the fourth land electrode are one integrated land electrode.

19. The multilayer-ceramic-capacitor mounting structure according to claim 16, wherein
the first plating electrode layer and the fifth plating electrode layer include a same material; and
the second plating electrode layer and the sixth plating electrode layer include a same material.

20. The multilayer-ceramic-capacitor mounting structure according to claim 19, wherein
the third plating electrode layer includes a same material as the first plating electrode layer and the fifth plating electrode layer; and
the fourth plating electrode layer includes a same material as the second plating electrode layer and the sixth plating electrode layer.
